(19) United States
(12) Patent Application Publication
(10) Pub. No.: US 2025/0261364 A1
(43) Pub. Date: Aug. 14, 2025

(54) ENHANCED SENSE AMPLIFIER ARCHITECTURE

(71) Applicant: Micron Technology, Inc., Boise, ID (US)

(72) Inventors: Daniele Vimercati, El Dorado Hills, CA (US); Veeresh Salimath, Folsom, CA (US)

(21) Appl. No.: 18/784,822

(22) Filed: Jul. 25, 2024

Related U.S. Application Data
(60) Provisional application No. 63/553,036, filed on Feb. 13, 2024.

(51) Int. Cl. H10B 12/00; G11C 11/4091

(52) U.S. Cl. CPC H10B 12/50; G11C 11/4091

(57) ABSTRACT

Methods, systems, and devices for an enhanced sense amplifier architecture are described. An architecture of p-type transistors in a sense amplifier may be modified to support greater accuracy of voltage sensing operations in a memory system. A shape and/or a positioning of one or more channel portions of a p-type transistor, relative to one or more gate portions of the p-type transistor, may increase an effective channel length of the p-type transistor, which may support an increased accuracy of cell voltage sensing. In some examples, a channel portion of the p-type transistor may have a non-rectangular shape to support a relatively longer electrical path between a source and a drain of the p-type transistor. In some examples, a shape of a gate portion of the p-type transistor may have a non-rectangular shape to support a relatively longer path between the source and the drain.

### CROSS REFERENCE

The present Application for Patent claims priority to U.S. Patent Application No. 63/553,036 by Vimercati et al., entitled “ENHANCED SENSE AMPLIFIER ARCHITECTURE,” filed Feb. 13, 2024, which is assigned to the assignee hereof, and which is expressly incorporated by reference in its entirety herein.

### TECHNICAL FIELD

The following relates to one or more systems for memory, including an enhanced sense amplifier architecture.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of an architecture that supports an enhanced sense amplifier architecture in accordance with examples as disclosed herein.

FIG. 2 shows an example of a circuit diagram that supports an enhanced sense amplifier architecture in accordance with examples as disclosed herein.

FIG. 3 shows an example of a sense amplifier that supports an enhanced sense amplifier architecture in accordance with examples as disclosed herein.

FIGS. 4A and 4B show an example of a transistor structure and a sense amplifier architecture that support an enhanced sense amplifier architecture in accordance with examples as disclosed herein.

FIGS. 5-8 show examples of sense amplifier architectures that support an enhanced sense amplifier architecture in accordance with examples as disclosed herein.

### DETAILED DESCRIPTION

In some memory systems, a sense amplifier may be used to determine a state stored by a memory cell. The sense amplifier may be coupled with an access line (e.g., a bit line, a word line) that is coupled with the memory cell. The memory cell may transfer charge to the access line after it is coupled with the access line. The sense amplifier may amplify low power signals from the access line to recognize logic levels (e.g., 0, 1) such that the data may be interpreted by the memory device. However, in some cases, the sense amplifier may experience degradations that cause errors in access operations at the memory device, causing read or write operations to be performed in error. For example, due to differences between manufacturing a first p-type transistor of the sense amplifier and manufacturing a second p-type transistor of the sense amplifier, the p-type transistor may drift from target voltage thresholds associated with the p-type transistor, causing the p-type transistor to behave different than expected behavior. Such variations in the performance of the p-type transistor (e.g., due to manufacturing variations, at least in part) may reduce the performance of the sense amplifier to accurately interpret data from access lines, which may result in various inefficiencies for memory access.

In accordance with examples described herein, an architecture of p-type transistors in a sense amplifier may be modified to support greater accuracy of voltage sensing operations in a memory system. For example, a shape and/or a positioning of one or more channel portions of a p-type transistor, relative to one or more gate portions of the p-type transistor, may increase an effective channel length of the p-type transistor, which may support an increased accuracy of cell voltage sensing. In some examples, a channel portion (e.g., channel region, active area) of the p-type transistor may have a non-rectangular shape (e.g., a ‘Z’ shape) to support a relatively longer path (e.g., conductive path) between a source and a drain of the p-type transistor, effectively increasing the channel length (e.g., a path, or distance, of travel of carriers in a channel portion of the transistor). In other examples, a shape of a gate portion of the p-type transistor may have a non-rectangular shape (e.g., a ‘half-H’ shape, a ‘C’ shape) to support a relatively longer path between the source and the drain.

In addition to applicability in memory systems as described herein, techniques for an enhanced sense amplifier architecture may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving accuracy and reliability of memory access operations, which may improve response times and result in more accurate and efficient memory access, among other benefits.

Features of the disclosure are illustrated and described in the context of architectures. Features of the disclosure are further illustrated and described in the context of circuit diagrams, sense amplifiers, transistor structures, and sense amplifier architectures.

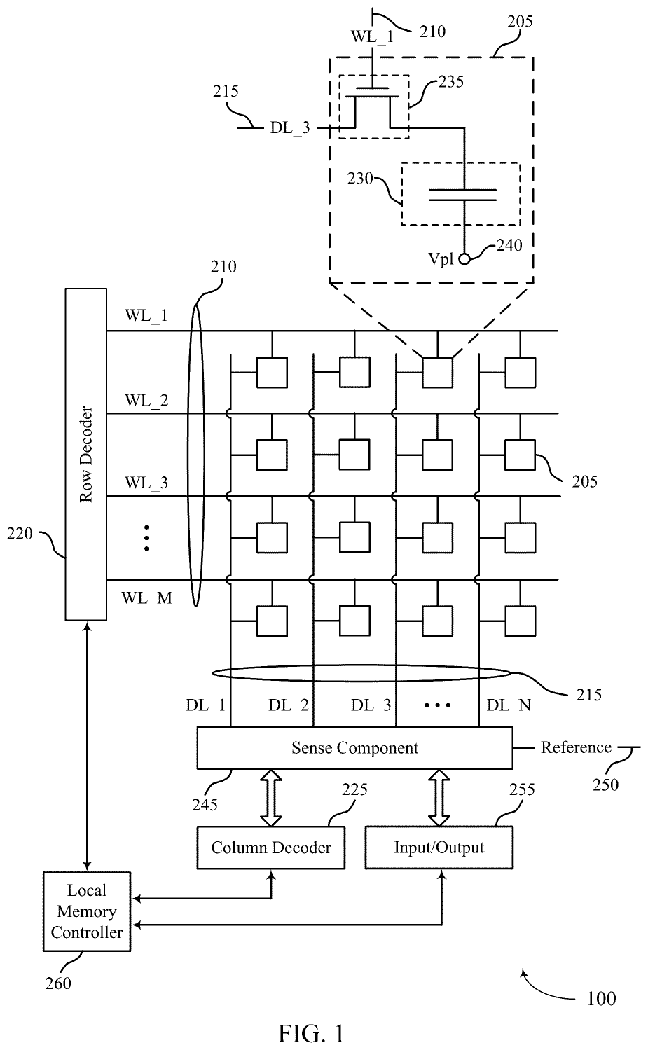

FIG. 1 illustrates an example of an architecture 100 (e.g., a memory architecture) that supports an enhanced sense amplifier architecture in accordance with examples as disclosed herein. The architecture 100 may be implemented in a memory system or one or more components thereof (e.g., memory device). Aspects of the architecture 100 may be referred to as or implemented in a semiconductor component, such as a memory die.

The architecture 100 includes memory cells 205 that are programmable to store information. In some examples, a memory cell 205 may be operable to store one bit of information at a time (e.g., a logic 0 or a logic 1). In some examples, a memory cell 205 (e.g., a multi-level memory cell) may be operable to store more than one bit of information at a time (e.g., a logic 00, logic 01, logic 10, a logic 11). Memory cells 205 may be arranged in an array, such as in a memory array.

In the example of architecture 100, a memory cell 205 may include a storage component, such as capacitor 230, and a selection component 235 (e.g., a cell selection component, a transistor). A capacitor 230 may be a dielectric capacitor or a ferroelectric capacitor. A node of the capacitor 230 may be coupled with a voltage source 240, which may be a cell plate reference voltage, such as Vpl, or may be a ground voltage, such as Vss. A charge stored by a memory cell 205 (e.g., by a capacitor 230) may be representative of a programmed state. Other memory architectures that support the techniques described herein may implement different types or arrangements of storage components and associated circuitry (e.g., with or without a selection component).

The architecture 100 may include various arrangements of access lines, such as word lines 210 and digit lines 215. An access line may be a conductive line that is coupled with a memory cell 205, and may be used to perform access operations on the memory cell 205. Word lines 210 may be referred to as row lines, and digit lines 215 may be referred to as column lines or bit lines, among other nomenclature. Memory cells 205 may be positioned at intersections of access lines, and an intersection may be referred to as an address of a memory cell 205.

In some architectures, a word line 210 may be coupled with a gate of a selection component 235 of a memory cell 205, and may be operable to control (e.g., switch, modulate a conductivity of) the selection component 235. A digit line 215 may be operable to couple a memory cell 205 with a sense component 245. In some architectures, a memory cell 205 (e.g., a capacitor 230) may be coupled with a digit line 215 during portions of an access operation. For example, a word line 210 and a selection component 235 of a memory cell 205 may be operable to couple or isolate a capacitor 230 of the memory cell 205 with a digit line 215.

Operations such as reading and writing may be performed on memory cells 205 by activating (e.g., applying a voltage to) access lines such as a word line 210 or a digit line 215. Accessing the memory cells 205 may be controlled through a row decoder 220, or a column decoder 225, or a combination thereof. For example, a row decoder 220 may receive a row address (e.g., from a local memory controller 260) and activate a word line 210 based on a received row address, and a column decoder 225 may receive a column address and activate a digit line 215 based on a received column address. Selecting or deselecting a memory cell 205 may include activating or deactivating a selection component 235 using a word line 210. For example, a capacitor 230 may be isolated from a digit line 215 when the selection component 235 is deactivated, and the capacitor 230 may be coupled with the digit line 215 when the selection component 235 is activated.

A sense component 245 may be operable to detect a state (e.g., a charge) stored by a capacitor 230 of a memory cell 205 and determine a logic state of the memory cell 205 based on the stored state. A sense component 245 may include one or more sense amplifiers to amplify or otherwise convert a signal resulting from accessing the memory cell 205. The sense component 245 may compare a signal detected from the memory cell 205 with a reference 250 (e.g., a reference voltage). The detected logic state of the memory cell 205 may be provided as an output of the sense component 245 (e.g., via an input/output 255), and may indicate the detected logic state to another component of a memory system that implements the architecture 100.

The local memory controller 260 may control the accessing of memory cells 205 through the various components (e.g., a row decoder 220, a column decoder 225, a sense component 245), and may be an example of or otherwise included in a local controller, or a memory system controller, or both. In some examples, one or more of a row decoder 220, a column decoder 225, and a sense component 245 may be co-located with or included in the local memory controller 260. The local memory controller 260 may be operable to receive commands or data from one or more different controllers (e.g., a host system controller, a memory system controller), translate the commands or the data into information that can be used by the architecture 100, initiate or control one or more operations of the architecture 100, and communicate data from the architecture 100 to a host (e.g., a host system) based on performing the one or more operations.

The local memory controller 260 may be operable to perform one or more access operations on one or more memory cells 205 of the architecture 100. Examples of an access operation may include a write operation, a read operation, a refresh operation, a precharge operation, or an activate operation, among others. In some examples, an access operation may be performed by or otherwise coordinated by the local memory controller 260 in response to one or more access commands (e.g., from a host system). The local memory controller 260 may be operable to perform other access operations not listed here or other operations related to the operating of the architecture 100 that are not directly related to accessing the memory cells 205.

To support an access operation, a local memory controller 260 may identify a target memory cell 205 on which to perform the access operation, which may be associated with identifying a target word line 210 and a target digit line 215 coupled with the target memory cell 205 (e.g., an address of the target memory cell 205). The local memory controller 260 may control activating the target word line 210 and the target digit line 215 to access the target memory cell 205. During a write operation, the local memory controller 260 may control the application of a signal (e.g., a write pulse, a write voltage) to the target digit line 215 to store a specific state (e.g., a charge, in a capacitor 230) of the memory cell 205. The signal used as part of the write operation may include one or more voltage levels applied to the target memory cell 205 (e.g., via the target digit line 215) over one or more respective durations. During a read operation, the target memory cell 205 may transfer a signal (e.g., charge, voltage) to the sense component 245 based on activating the target word line 210 and the target digit line. The local memory controller 260 may activate the sense component 245 (e.g., initiate latching a sense amplifier of the sense component 245), which may include comparing the signal transferred from the memory cell 205 to a reference (e.g., the reference 250). Based on the comparison, the sense component 245 may determine a logic state that is stored on the memory cell 205.

In some examples, a sense component 245 may include p-type transistors and n-type transistors which support a function of the sense component 245 to perform access operations. However, the p-type transistors and n-type transistors of the sense component 245 may have voltage thresholds or target voltages that differ from one transistor to another transistor. A lack of uniformity among p-type transistors in the sense component 245 may result in inaccuracies in sensing voltages for memory access operations. In accordance with examples described herein, an architecture of sense amplifiers that are within, or part of, the sense component 245 may be modified to increase an effective channel length of p-type transistors within the sense component 245, which may support an increased accuracy of voltage sensing operations by the sense component 245.

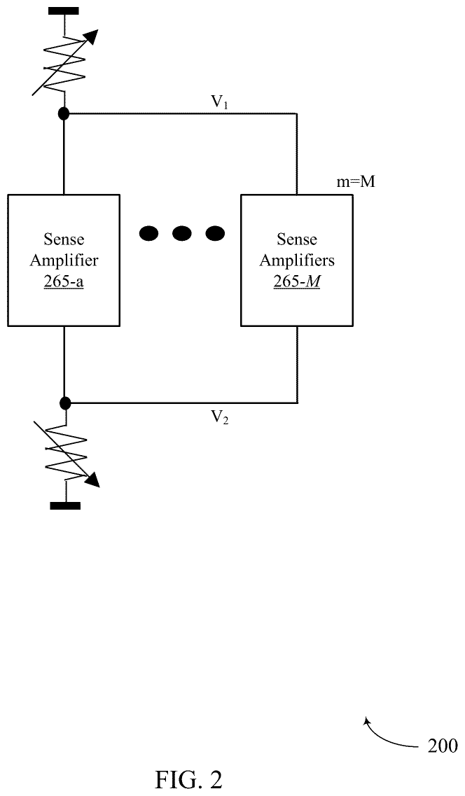

FIG. 2 shows an example of a circuit diagram 200 that supports an enhanced sense amplifier architecture in accordance with examples as disclosed herein. The circuit diagram 200 may include a sense amplifier 265-a and other sense amplifiers 265, which may be components of a sense component 245, as described with reference to FIG. 1. For example, the sense component 245 may include one or more sense amplifiers 265 including the sense amplifier 265-a through 265-M (where M is a variable). The sense amplifier 265-a may amplify data signals from an access line which may enable the sense component 245 to interpret the data signals to logic (e.g., 0, 1).

In some examples, a sense component 245 may include a plurality of sense amplifiers 265 each coupled with one access line of a plurality of access lines (e.g., bit lines). From a power perspective, the plurality of sense amplifiers may be coupled in a parallel configuration to various voltage sources (e.g., V₁ and V₂). In some examples, a sense amplifier 265-a may be connected in parallel with other sense amplifiers 265 (e.g., M other sense amplifiers 265), and the sense amplifiers 265 connected in parallel may share one or more common voltage sources (e.g., V₁ and V₂). The common voltage sources may output a voltage V₁ on a first voltage line of the sense amplifiers 265 and a voltage V₂ on a second voltage line of the sense amplifiers 265. The voltages V₁ and V₂ may be based on a combined load of the sense amplifiers 265. For example, the voltages V₁ and V₂ may vary based on the accumulated electrical responses of the load (e.g., the plurality of sense amplifiers) coupled with the voltages V₁ and V₂.

An actual voltage difference (e.g., dVₜₕ) for the sense amplifier 265-a may differ from an average sense amplifier (e.g., due to manufacturing inconsistencies of the sense amplifiers). However, because the other sense amplifiers 265 share a voltage source with the sense amplifier 265-a dictate the values of V₁ and V₂, the sense amplifier 265-a may adapt to function according to the common power supply. Thus, in some cases, an individual sense amplifier 265 may have an ideal operating voltage at a first value due to its manufacturing variations, but its operating voltage may be different than the ideal operating voltage because the voltage on the common voltage sources is a product of the entire electrical load. In some examples, because the sense amplifier 265-a is connected in parallel with the other sense amplifiers 265, the sense amplifier 265-a may also share a voltage threshold compensation (VTC) time with the other sense amplifiers 265. The sense amplifier 265-a may adapt to function according to the common VTC time.

The sense amplifier 265-a may adapt to the common voltage source (e.g., common dVₜₕ), and a behavior of the sense amplifier 265-a may vary from an expected behavior of the sense amplifier 265-a (e.g., based on a difference between an ideal operating voltage for the individual sense amplifier and the actual operating voltage). The sense amplifier 265-a may operate with an inefficient voltage sensing behavior due to the common voltage source outputting voltage values that are different from an actual threshold voltage difference (e.g., dVₜₕ), that accounts for a skew of the sense amplifier 265-a with respect to the average of the sense amplifiers 265. Thus, the sense amplifier 265-a may amplify data values from a digit line with some error, which may cause reads from the digit line to be inaccurate. In accordance with examples described herein, an architecture of a p-type transistor (e.g., a p-channel metal oxide semiconductor (PMOS)) may be modified to reduce the effect of variations of the common voltage source across sense amplifiers 265 connected in parallel. For example, an effective channel length of the p-type transistor in the sense amplifier 265-a may be increased, which may reduce variation in voltage sensing of the sense amplifier 265-a, for example in cases where a mismatch exists between the common voltage source of the sense amplifier 265-a and the characteristics (e.g., voltage thresholds) of the sense amplifier 265-a, resulting in increased performance.

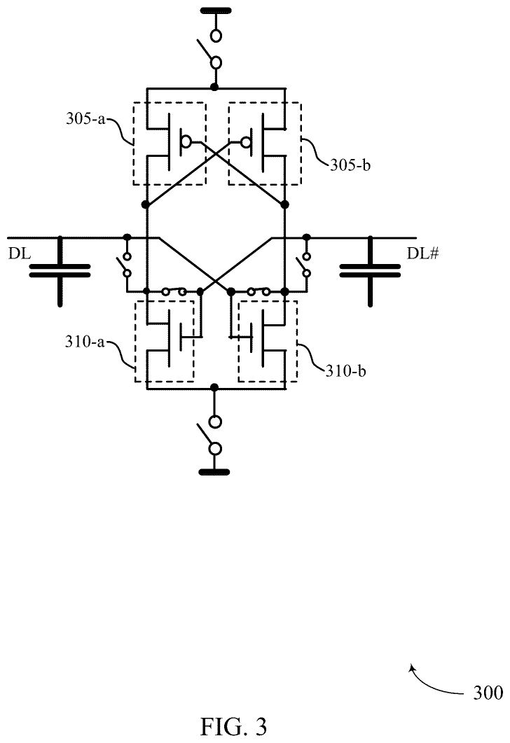

FIG. 3 shows an example of a sense amplifier 300 that supports an enhanced sense amplifier architecture in accordance with examples as disclosed herein. The sense amplifier 300 may be an example of a component of a sense component 245, as described with reference to FIG. 1. For example, the sense component 245 may include the sense amplifier 300, and the sense amplifier 300 may amplify data signals from an access line, which may enable the sense component 245 to interpret the data signals to logic (e.g., 0, 1).

The sense amplifier 300 may include a p-type transistor 305-a, a p-type transistor 305-b, an n-type transistor 310-a, and an n-type transistor 310-b. The n-type transistors 310 may be connected in a diode mode (e.g., a metal oxide semiconductor (MOS) diode connection). For example, the n-type transistor 310-b may act as a diode and may take as an input voltage from a digit line (e.g., DL) and connect (e.g., pass) the voltage from the digit line to a source of the p-type transistor 305-b. The p-type transistor 305-b may amplify the voltage from the digit line to produce a digit line bar (e.g., DL #). The amplified voltage at the digit line bar may be used by the sense component 245 to interpret data from the digit line into logic.

In some examples, the sense amplifier 300 may be inefficient in amplifying data from the digit line for read operations at the sense component 245. Output voltages of the sense amplifier 300 may be associated with tails that prevent data from the digit line from being read and interpreted accurately. Inefficiencies of the sense amplifier 300 may be caused by inconsistencies associated with either of the n-type transistors or the p-type transistors or inconsistencies of the interactions between the n-type transistors and the p-type transistors.

In some cases, the n-type transistors 310-a and 310-b may be associated with small inconsistencies relative to expected performance of an n-type transistor 310. Due to these inconsistencies, the n-type transistor 310-b may output a voltage, though the n-type transistor is operating in a diode mode, that is inconsistent with the voltage of the digit line. When the n-type transistor passes the output voltage to a source of the p-type transistor 305-b, any differences in voltage caused by the n-type transistor may be amplified by the p-type transistor 305-b performing amplification on the voltage.

In some examples, in addition to inconsistencies of the n-type transistors 310, the p-type transistors 305 may be associated with various inconsistencies (e.g., variations from expected behavior). In particular, the p-type transistor 305-b, for example, may operate with a voltage threshold difference (e.g., dVₜₕ) that may differ from that of a typical p-type transistor 305-b, and that may differ from that of the p-type transistor 305-a. Such a difference in the operating voltage threshold difference for p-type transistors 305 within the sense amplifier 300 may result in relatively large tails associated with the voltage sensing performance of the sense amplifier 300.

In some cases, there may exist a large spread (e.g., 0.5 uA to 15 uA) of operative currents for the p-type transistors 305 and the n-type transistors 310, which may be a product of offsets corresponding to variations in the p-type transistor 305 and the n-type transistor 310. Such a large current spread may be due to the p-type transistor 305 operating in a transition region between below a threshold voltage of the p-type transistor 305 (e.g., sub-Vth) and above the voltage threshold (e.g., above-Vth).

In some examples, to improve the performance of the sense amplifier 300, an architecture of channel portions and gate portions within a p-type transistor 305 may be modified. Modifying the architecture for the p-type transistor 305 may improve the performance of the sense amplifier 300 for cell voltage sensing, thereby increasing a range of cell voltages that may be sensed (e.g., interpreted) correctly. In accordance with examples described herein, an effective channel length of the p-type transistor 305 may be increased, which may enable the p-type transistor 305 to have improved sensing performance. For example, a difference in a threshold voltage difference from one p-type transistor (e.g., the p-type transistor 305-a) to another p-type transistor (e.g., the p-type transistor 305-b) may have relatively less impact on sensing performance for the sense amplifier 300 due to the enhanced architecture of the p-type transistor 305 of the sense amplifier 300.

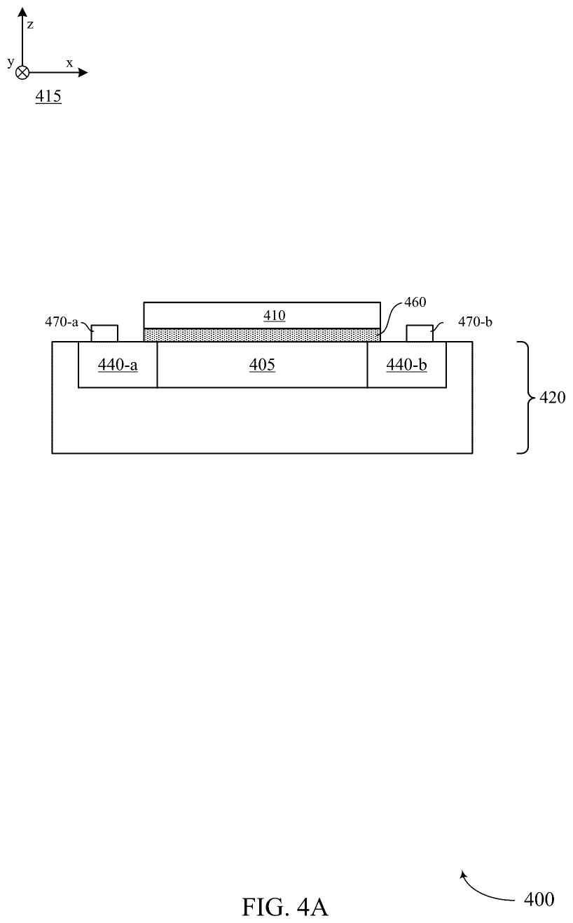

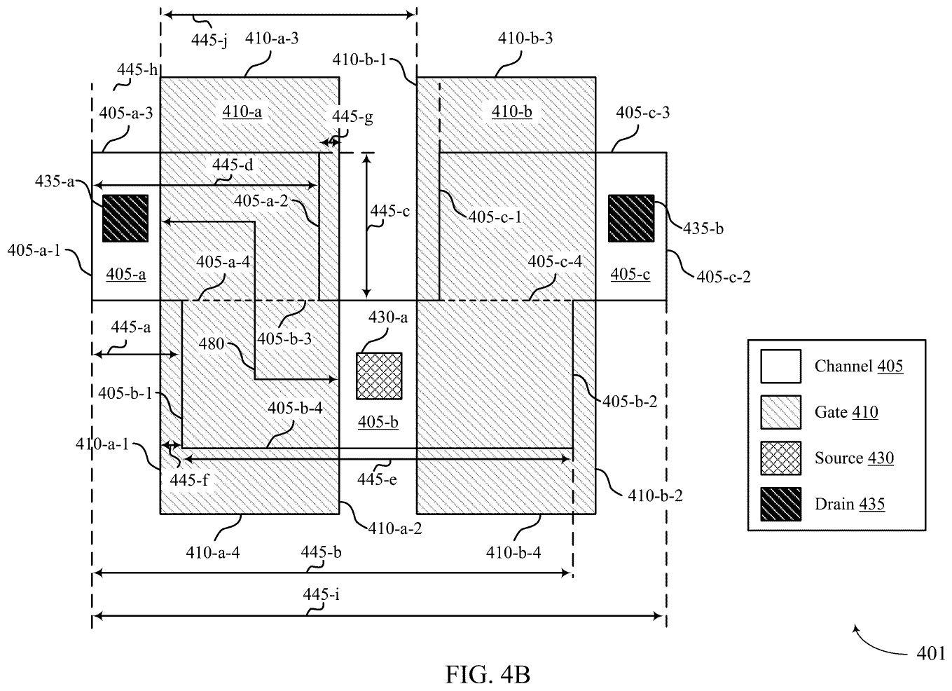

FIG. 4A shows an example of a transistor structure 400 that supports an enhanced sense amplifier architecture in accordance with examples as disclosed herein. The transistor structure 400 illustrates an example of a transistor that is formed at least in part by portions of a substrate 420 (e.g., doped portions 440 of the substrate 420), and may illustrate an arrangement of features for a transistor that is configured in a planar transistor arrangement. The substrate 420 may be a portion of a semiconductor chip, such as a silicon chip of a memory die (e.g., crystalline silicon, monocrystalline silicon). For illustrative purposes, aspects of the transistor structure 400 may be described with reference to an x-direction, a y-direction, and a z-direction of a coordinate system 415. In some examples, the z-direction may be illustrative of a direction perpendicular to a surface of the substrate 420 (e.g., a surface in an xy-plane, a surface upon or over which other materials may be deposited), and each of the structures, illustrated by their respective cross section in an xz-plane, may extend for some distance (e.g., length) in the y-direction.

The transistor structure 400 illustrates an example of a transistor channel, electrically coupled between a terminal 470-a and a terminal 470-b, that may include one or more doped portions 440 of the substrate 420. In various examples, one of the terminals 470-a or 470-b may be referred to as a source terminal, and the other of the terminals 470-a or 470-b may be referred to as a drain terminal, where such designation or nomenclature may be based on a configuration or relative biasing of a circuit that includes the transistor structure 400. The channel (e.g., a channel portion 405) of a transistor may include or refer to one or more portions of the transistor structure that are operable to open or close a conductive path between a source and drain (e.g., between the terminal 470-a and the terminal 470-b) based at least in part on a voltage of a gate (e.g., a gate terminal, a gate portion 410). In other words, a channel portion 405 of a transistor structure may be doped in a way to create a conductive path between the terminals 470-a and 470-b in response to a voltage being applied to the gate portion 410. The channel portion 405 may be activated, deactivated, made conductive, or made non-conductive, based at least in part on a voltage of a gate portion, such as gate portion 410. In some examples of transistor structure 400 (e.g., a planar transistor arrangement), the channel portion 405 formed by one or more doped portions 440 of the substrate 420 may support a conductive path in a generally horizontal or in-plane direction (e.g., along the x-direction, within an xy-plane, in a direction within or parallel to a surface of the substrate 420).

In some examples, the gate portion 410 may be physically separated from the channel portion 405 (e.g., separated from the substrate 420, separated from one or more of the doped portions 440) by a gate insulation portion 460. Each of the terminals 470 may be in contact with or otherwise coupled with (e.g., electrically, physically) a respective doped portion 440-a, and each of the terminals 470 and the gate portion 410 may be formed from an electrically conductive material such as a metal or metal alloy, or a polycrystalline semiconductor (e.g., polysilicon).

In some examples, the transistor structure 400 may be operable as an n-type or n-channel transistor. In the case of an n-type transistor, applying a relatively positive voltage to the gate portion 410 that is above a threshold voltage (e.g., an applied voltage having a positive magnitude, relative to a source terminal, that is greater than a threshold voltage) activates the channel portion 405 or otherwise enables a conductive path between the terminals 470-a and 470-b (e.g., along a direction generally aligned with the x-direction within the substrate 420). In such examples, the doped portion 440-a and the doped portion 440-b may refer to portions having n-type doping or n-type semiconductor.

In some examples, the transistor structure 400 may be operable as a p-type or p-channel transistor. In the case of a p-type transistor, applying a relatively negative voltage to the gate portion 410 that is above a threshold voltage (e.g., an applied voltage having a negative magnitude, relative to a source terminal, that is greater than a threshold voltage) activates the channel portion 405 or otherwise enables a conductive path between the terminals 470-a and 470-b. In such examples, the doped portion 440-a and the doped portion 440-b may refer to portions having p-type doping or p-type semiconductor.

In some examples, a distance that the charge carriers travel in the channel portion 405 may be associated with the conductive path between the terminals 470-a and 470-b. The distance may be referred to as the channel length. The channel length may be a distance that an average carrier travels from the terminal 470-a to the terminal 470-b when the transistor is activated (e.g., when the gate portion 410 activates the channel portion 405 to form a conductive path). In some examples, the channel portion 405 may be modified to increase the channel length, which may provide improvements in accuracy to a sense component (e.g., a sense component 245) for performing cell voltage sensing. For example, the threshold voltage of the p-type transistor is at least partially based on the length of the channel in the transistor. The shorter the channel length, the more susceptible to variations the threshold voltage of the transistor is. The p-type transistors in the sense amplifier are configured as amplifiers. If the p-type transistor is not fully thresholded (e.g., due to variations in the threshold voltage), the amplification provided by the p-type transistor may vary, which may cause the performance of the sense amplifier to vary. To reduce the variability of the threshold voltage of the p-type transistor, techniques may be used to increase the channel length of the transistor (without increasing the size of the transistor). In accordance with examples described herein, various architectures of the channel portion 405 and the gate portion 410 may be utilized to lengthen the effective channel length of carriers passing through the channel portion 405.

FIG. 4B shows an example of a sense amplifier architecture 401 that supports an enhanced sense amplifier architecture in accordance with examples as disclosed herein. The sense amplifier architecture 401 may illustrate an example architecture of a p-type transistor 305-a and a p-type transistor 305-b of a sense amplifier 300, as described with reference to FIG. 3.

In some examples, the channel portion 405 of the transistor structure 400, as described with reference to FIG. 4, may be partitioned (e.g., logically partitioned and not necessarily physically partitioned) into a channel portion 405-a, a channel portion 405-b, and a channel portion 405-c. The sense amplifier architecture 401 may illustrate a top-down view of the transistor structure 400 as illustrated in FIG. 4A, and the channel portions 405 and gate portions 410 may be on distinct layers such that the gate portions 410 are positioned above the channel portions 405.

As described in greater detail with reference to FIG. 4A, the gate portions 410 may activate the channel portions 405, which, when activated, may form a conductive path between a source 430 and a drain 435. An example of a first channel between a source 430-a and a drain 435-a, corresponding to a first transistor of a sense amplifier, may be illustrated by a channel path 480. There may also exist a second channel between the source 430-a and the drain 435-b, corresponding to a second transistor of the sense amplifier, where both transistors share the common source 430-a.

A first channel portion 405-a may be coupled with the drain 435-a and may include an edge 405-a-1, an edge 405-a-2 opposite the edge 405-a-1, an edge 405-a-3 extending between the edge 405-a-1 and the edge 405-a-2, and an edge 405-a-4 opposite the edge 405-a-3. A second channel portion 405-b may be coupled with the source 430-a (e.g., a common source between two transistors) and may include an edge 405-b-1, an edge 405-b-2, an edge 405-b-3, and an edge 405-b-4, in similar manner to the channel portion 405-a but offset relative to the channel portion 405-a. For example, the edge 405-b-1 may be offset from the edge 405-a-1 by a first distance 445-a and the edge 405-b-2 may be offset from the edge 405-a-1 by a second distance 445-b greater than the first distance. The edge 405-b-3 may be offset from the edge 405-a-3 by a third distance 445-c equal to a length of the edge 405-a-1. A width of the channel portion 405-a may be less than a width of the channel portion 405-b such that a fifth distance 445-d between edges 405-a-1 and 405-a-2 may be less than a sixth distance 445-e between edges 405-b-1 and 405-b-2. The channel portion 405-a and the channel portion 405-b may contact one another, forming a contiguous plane. For example, a portion of the edge 405-a-4 may contact a portion of the edge 405-b-3.

A gate portion 410-a, which may overlap at least a portion of the channel portion 405-a and the channel portion 405-b, may include an edge 410-a-1, an edge 410-a-2 opposite the edge 410-a-1, an edge 410-a-3 extending between the edge 410-a-1 and the edge 410-a-2, and an edge 410-a-4 opposite the edge 410-a-3. The edge 410-a-1 may be offset from the edge 405-b-1 by a seventh distance 445-f and the edge 410-a-2 may be offset from the edge 405-a-2 by an eighth distance 445-g different from the seventh distance 445-f (e.g., in an opposite direction relative to the seventh distance). The edge 410-a-3 may be offset from the edge 405-a-3 and the edge 410-a-4 may be offset from the edge 405-b-4.

A third channel portion may be coupled with the drain 435-b and may include an edge 405-c-1, an edge 405-c-2 opposite the edge 405-c-1, an edge 405-c-3 extending between the edge 405-c-1 and the edge 405-c-2, and an edge 405-c-4 opposite the edge 405-c-3. The edge 405-c-1 may be offset from the edge 405-a-1 by a ninth distance 445-h different from the first distance 445-a and the edge 405-c-2 may be offset from the edge 405-a-1 by a tenth distance 445-i different from the second distance 445-b. The channel portion 405-c and the channel portion 405-b may contact one another, forming a contiguous plane. For example, a portion of the edge 405-c-4 may contact a portion of the edge 405-b-3.

A gate portion 410-b, which may overlap at least a portion of the channel portion 405-c and the channel portion 405-b, may include an edge 410-b-1, an edge 410-b-2 opposite the edge 410-b-1, an edge 410-b-3 extending between the edge 410-b-1 and the edge 410-b-2, and an edge 410-b-4 opposite the edge 410-b-3. The edge 410-a-1 may be offset from the edge 410-b-1 by an eleventh distance 445-j different from the first distance 445-a and the second distance and the edge 410-a-2 may be offset from the edge 410-b-2 by the eleventh distance 445-j (e.g., the gate portion 410-a and the gate portion 410-b may be the same width).

The shape of the channel portion 405 illustrated in FIG. 4B is designed to increase a distance that carriers travel in the channel portion 405. For example, the source and the drains are offset from each other in a first direction and the channel portion 405 has a zig-zag pattern that increases the distance that carriers would travel, relative to the channel portion being a solid rectangle (e.g., a single rectangle without portions or offsets) or the sources and drains being aligned. For example, on average, carriers traveling through the channel portion 405 (e.g., a conductive path of the channel portion 405) may travel according to a channel path 480 (e.g., a ‘Z’-shaped path), which may be a greater distance relative to the channel portion being the solid rectangle or the sources and drains being aligned. This increased distance reduces the variability of the threshold voltage in the p-type transistor, which decreases the variations in performance of a sense amplifier that includes such p-type transistors.

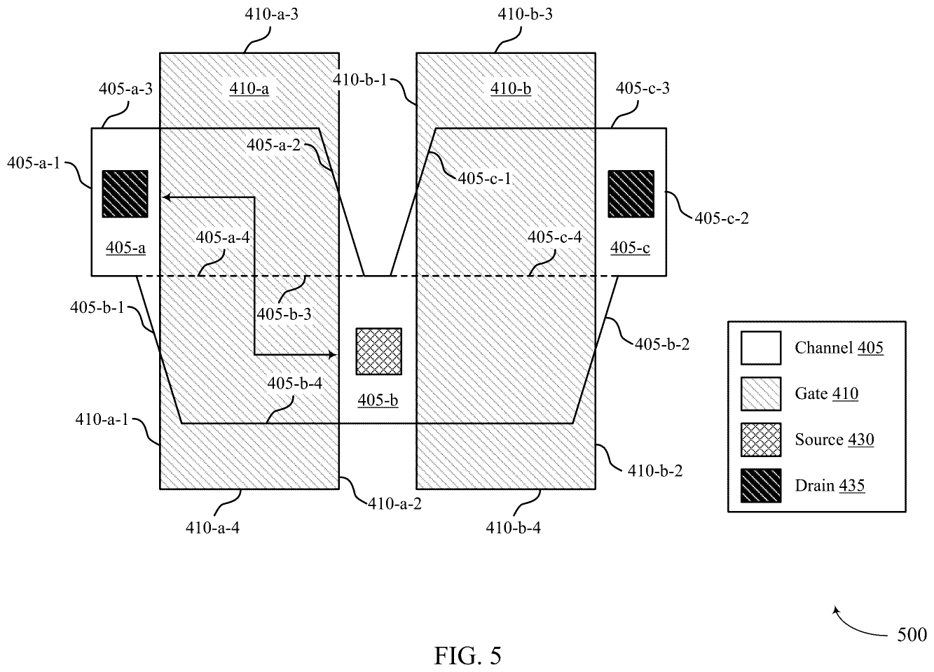

FIG. 5 shows an example of a sense amplifier architecture 500 that supports an enhanced sense amplifier architecture in accordance with examples as disclosed herein. The sense amplifier architecture 500 may illustrate an example architecture of a p-type transistor 305-a and a p-type transistor 305-b of a sense amplifier 300, as described with reference to FIG. 3. The sense amplifier architecture 500 is also an example of a variation on the sense amplifier architecture 401 described with reference to FIG. 4B. More specifically, the sense amplifier architecture 500 has some edges that are more angled relative to each other than the sense amplifier architecture 401, which has edges that are more perpendicular relative to each other. For example, the edge 405-b-1, the edge 405-a-2, the edge 405-b-2, and the edge 405-c-1 may be set at an angle in the sense amplifier architecture 500, relative to corresponding edges in the sense amplifier architecture 401. Other edges of the sense amplifier architecture 500 may be the same between the sense amplifier architecture 401 and the sense amplifier architecture 500, or may include similar relationships relative to the edges 405 of the sense amplifier architecture 401.

In the example of sense amplifier architecture 500, the edge 405-a-2 may be set at a first angle relative to the edge 405-a-1. The edge 405-b-1 may also be set at the first angle relative to the edge 405-a-1, such that the edge 405-b-1 is parallel with respect to the edge 405-a-2, or may be set at a different angle from the first angle. The edge 405-c-1 may be set at a second angle relative to the edge 405-c-2. The edge 405-b-2 may also be set at the second angle relative to the edge 405-c-2, such that the edge 405-b-2 is parallel with respect to the edge 405-c-1, or may be set at a different angle from the second angle.

In some examples, positioning one or more edges of one or more channel portions 405 at angles relative to other edges may result in reduced complexity or reduced cost in manufacturing the one or more channel portions 405.

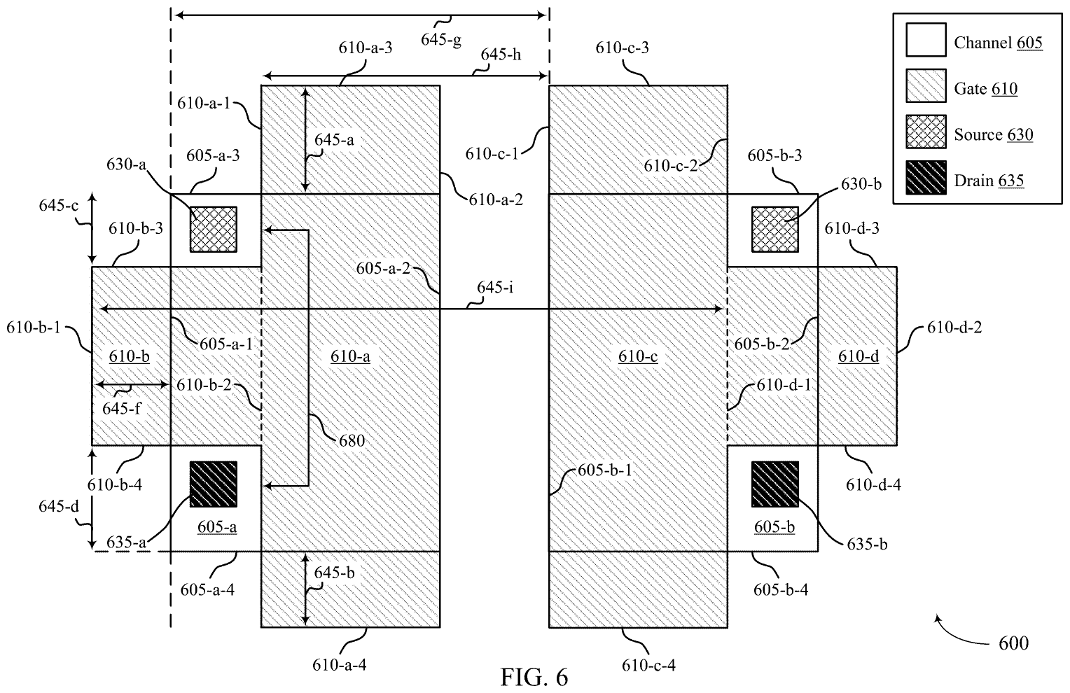

FIG. 6 shows an example of a sense amplifier architecture 600 that supports an enhanced sense amplifier architecture in accordance with examples as disclosed herein. The sense amplifier architecture 600 may illustrate an example architecture of a p-type transistor 305-a and a p-type transistor 305-b of a sense amplifier 300, as described with reference to FIG. 3.

In some examples, the gate portions 610 may be partitioned into a gate portion 610-a, a gate portion 610-b, a gate portion 610-c, and a gate portion 610-d. As described in greater detail with reference to FIG. 4A, the gate portions 610 may activate the channel portions 605, which, when activated, may form a conductive path between a source 630 and a drain 635. An example of a first channel between a source 630-a and a drain 635-a, corresponding to a first transistor of a sense amplifier, may be illustrated by a channel path 680. There may also exist a second channel between the source 630-b and the drain 635-b, corresponding to a second transistor of the sense amplifier.

A channel portion 605-a may include an edge 605-a-1, an edge 605-a-2, an edge 605-a-3, and an edge 605-a-4. A gate portion 610-a, which may overlap at least a first portion of the channel portion 605-a, may include an edge 610-a-1, an edge 610-a-2 opposite the edge 610-a-1, an edge 610-a-3 extending between the edge 610-a-1 and the edge 610-a-2, and an edge 610-a-4 opposite the edge 610-a-3. The edge 610-a-2 may align with a portion of the edge 605-a-2. The edge 610-a-3 may be offset from the edge 605-a-3 by a first distance 645-a. The edge 610-a-4 may be offset from the edge 605-a-4 by a second distance 645-b.

A gate portion 610-b, which may overlap at least a second portion of the channel portion 605-a different from the first portion of the channel portion 605-a, may include an edge 610-b-1, an edge 610-b-2 opposite the edge 610-b-1, an edge 610-b-3 extending between the edge 610-b-1 and the edge 610-b-2, and an edge 610-b-4 opposite the edge 610-b-3. The gate portion 610-a and the gate portion 610-b may contact one another, forming a contiguous plane. For example, the edge 610-b-2 may contact a portion of the edge 610-a-1. The edge 610-b-1 may be offset from the edge 605-a-1 by a distance 645-f. The edge 610-b-3 may be offset from the edge 605-a-3 by a third distance 645-c. The edge 610-b-4 may be offset from the edge 605-a-4 by a fourth distance 645-d. The edge 610-a-1 may be offset from the edge 605-a-1 by a fifth distance 645-e.

A second channel portion 605-b, corresponding to another p-type transistor, may include an edge 605-b-1, an edge 605-b-2, an edge 605-b-3, and an edge 605-b-4, in like manner to the channel portion 605-b, but offset relative to the channel portion 605-b. For example, the edge 605-a-1 may be offset from the edge 605-b-1 by a sixth distance 645-g and the edge 605-a-2 may be offset from the edge 605-b-2 by the sixth distance 645-g (e.g., the channel portion 605-a and the channel portion 605-b may be the same width). A gate portion 610-c may include an edge 610-c-1, an edge 610-c-2, an edge 610-c-3, and an edge 610-c-4, in like manner to the gate portion 610-a, but offset relative to the gate portion 610-a. For example, the edge 610-c-1 may be offset from the edge 610-a-1 by a seventh distance 645-h and the edge 610-c-2 may be offset from the edge 610-a-2 by the seventh distance 645-h. A gate portion 610-d may include an edge 610-d-1, an edge 610-d-2, an edge 610-d-3, and an edge 610-d-4, in like manner to the gate portion 610-b, but offset relative to the gate portion 610-b. For example, the edge 610-d-1 may be offset from the edge 610-b-1 by an eighth distance 645-i and the edge 610-d-2 may be offset from the edge 610-b-2 by the eighth distance 645-i.

The shape of the gate portion 610 illustrated in FIG. 6 is designed to increase a distance that carriers travel in the channel portion 605. For example, though the source 630 and the drain 635 are aligned vertically, and some carriers traveling through the channel portion 605 may pass directly through the channel portion overlapping the gate portion 610-b, other carriers may travel a greater distance through the channel portion overlapping the gate portion 610-a, in a ‘C’-shaped trajectory or path of travel, illustrated by the channel path 680. Between the two paths of travel, which may average to a ‘C’-shaped path of travel, the carriers may travel a greater distance relative to the gate portion 610 being a solid rectangle (e.g., a single rectangle without portions or offsets). This increased distance reduces the variability of the threshold voltage in the p-type transistor, which decreases the variations in performance of a sense amplifier that includes such p-type transistors.

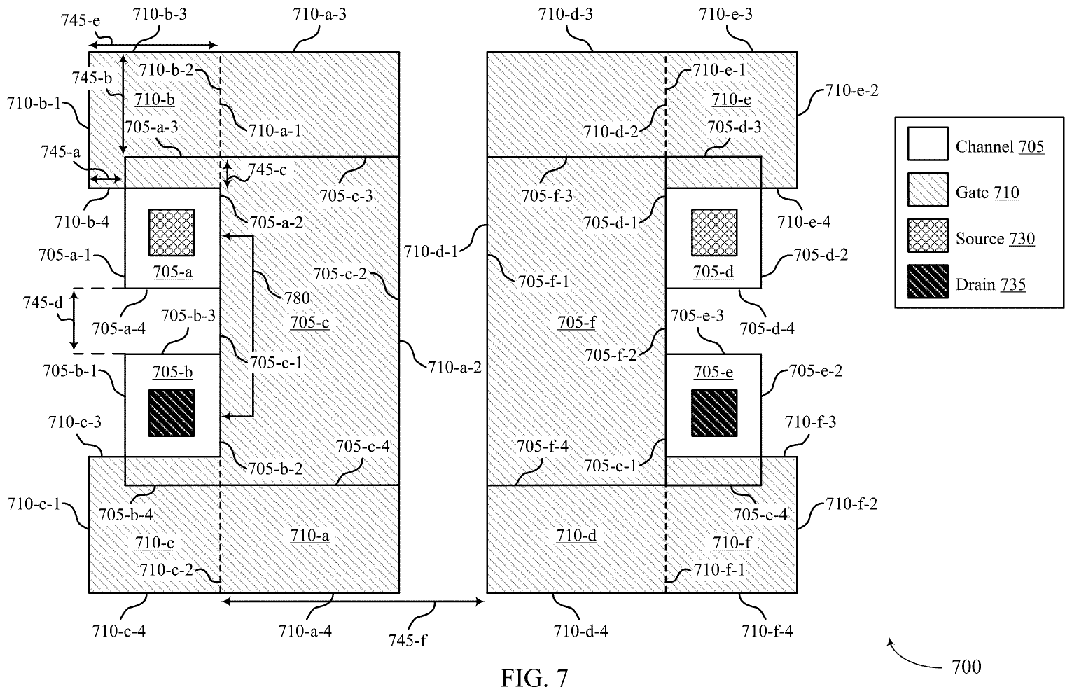

FIG. 7 shows an example of a sense amplifier architecture 700 that supports an enhanced sense amplifier architecture in accordance with examples as disclosed herein. The sense amplifier architecture 700 may illustrate an example architecture of a p-type transistor 305-a and a p-type transistor 305-b of a sense amplifier 300, as described with reference to FIG. 3.

In some examples, channel portions 705 may be partitioned into a channel portion 705-a, a channel portion 705-b, a channel portion 705-c, a channel portion 705-d, a channel portion 705-e, and a channel portion 705-f, and gate portions 710 may be partitioned into a gate portion 710-a, a gate portion 710-b, a gate portion 710-c, a gate portion 710-d, a gate portion 710-e, and a gate portion 710-f. As described in greater detail with reference to FIG. 4A, the gate portions 710 may activate the channel portions 705, which, when activated, may form a conductive path between a source 730 and a drain 735. An example of a first channel between a source 730 and a drain 735, corresponding to a first transistor of a sense amplifier, may be illustrated by a channel path 780. There may also exist a second channel between another source 730 and another drain 735, corresponding to a second transistor of the sense amplifier.

The channel portion 705-a may include an edge 705-a-1, an edge 705-a-2, an edge 705-a-3, and an edge 705-a-4. The channel portion 705-b may include an edge 705-b-1, an edge 705-b-2, an edge 705-b-3, and an edge 705-b-4. The channel portion 705-c may include an edge 705-c-1, an edge 705-c-2, an edge 705-c-3, and an edge 705-c-4. The edge 705-c-3 may extend from the edge 705-a-3 in a first direction and the edge 705-c-4 may extend from the edge 705-b-4 in the first direction.

The gate portion 710-b may include an edge 710-b-1, an edge 710-b-2, an edge 710-b-3, and an edge 710-b-4. The edge 710-b-1 may be offset from the edge 705-a-1 by a first distance 745-a. The edge 710-b-3 may be offset from the edge 705-a-3 by a second distance 745-b and the edge 710-b-4 may be offset from the edge 705-a-3 by a third distance 745-c. The gate portion 710-c may include an edge 710-c-1, an edge 710-c-2, an edge 710-c-3, and an edge 710-c-4. The edge 710-c-1 may be offset from the edge 705-b-1 by the first distance 745-a. The edge 710-c-4 may be offset from the edge 705-b-4 by the second distance 745-b and the edge 710-c-3 may be offset from the edge 705-b-4 by the third distance 745-c.

The gate portion 710-a may include an edge 710-a-1, an edge 710-a-2, an edge 710-a-3, and an edge 710-a-4. A portion of the edge 710-a-2 may be aligned with the edge 705-c-2. The edge 710-b-2 may contact a first portion (e.g., segment) of the edge 705-c-1 and the edge 710-c-2 may contact a second portion (e.g., segment) of the edge 705-c-1.

The edge 705-a-4 may be offset from the edge 705-b-3 by a fourth distance 745-d. The gate portion 710-b and the gate portion 710-c may be associated with an overhang relative to the gate portion 710-a, to form a ‘C’ shape architecture, such that the edge 710-b-1 is offset from the edge 705-c-1 by a fifth distance 745-e and the edge 710-c-1 is offset from the edge 705-c-1 by the fifth distance 745-e.

Channel portions 705-d, 705-e, and 705-f, corresponding to another p-type transistor, may include an edge 705-d-1, an edge 705-d-2, an edge 705-d-3, an edge 705-d-4, an edge 705-e-1, an edge 705-e-2, an edge 705-e-3, an edge 705-e-4, an edge 705-f-1, an edge 705-f-2, an edge 705-f-3, and an edge 705-f-4, in like manner to the channel portions 705-a, 705-b, and 705-c, respectively, but with offsets (e.g., horizontal offsets) relative to the channel portions 705-a, 705-b, and 705-c. For example, the edge 705-c-1 may be offset from the edge 705-f-1 by a sixth distance 745-f and the edge 705-c-2 may be offset from the edge 705-f-2 by the sixth distance 745-f, offsetting the channel portion 705-c from the channel portion 705-f. Similarly, the channel portion 705-a may be offset from the channel portion 705-d, and the channel portion 705-b may be offset from the channel portion 705-e.

The shapes of the gate portion 710 and the channel portions 705 illustrated in FIG. 7 is designed to increase a distance that carriers travel in the channel portion 705. For example, due to there being a physical separation between the channel portion 705-a and the channel portion 705-b, a direct path between the source 730 and the drain 735 may not exist. Instead, carriers may travel through the channel portion 705-c, in a ‘C’-shaped trajectory or path of travel, illustrated by the channel path 780, which may be a greater distance for carriers to travel relative to the channel portion 705 and the gate portion 710 being solid rectangles (e.g., each being single rectangles without portions or offsets) with a direct path (e.g., conductive path) between source and drain. This increased distance reduces the variability of the threshold voltage in the p-type transistor, which decreases the variations in performance of a sense amplifier that includes such p-type transistors.

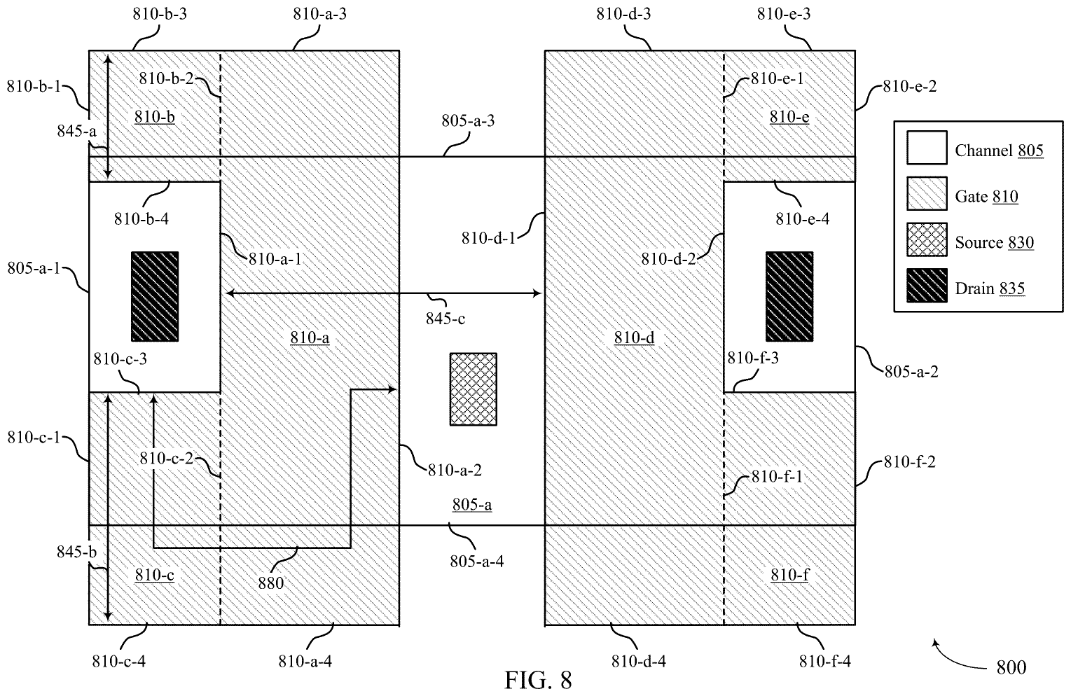

FIG. 8 shows an example of a sense amplifier architecture 800 that supports an enhanced sense amplifier architecture in accordance with examples as disclosed herein. The sense amplifier architecture 800 may illustrate an example architecture of a p-type transistor 305-a and a p-type transistor 305-b of a sense amplifier 300, as described with reference to FIG. 3.

A channel portion 805-a may be an example of a channel portion 805 and may include an edge 805-a-1, an edge 805-a-2, an edge 805-a-3, and an edge 805-a-4. In some examples, gate portions 810 may be partitioned into a gate portion 810-a, a gate portion 810-b, a gate portion 810-c, a gate portion 810-d, a gate portion 810-e, and a gate portion 810-f. As described in greater detail with reference to FIG. 4A, the gate portions 810 may activate the channel portion 805-a, which, when activated, may form a conductive path between a source 830 and a drain 835. An example of a first channel between a source 830 and a drain 835, corresponding to a first transistor of a sense amplifier, may be illustrated by a channel path 880. There may also exist a second channel between the source 830, which may be a common source between the two transistors, and a drain 835, corresponding to a second transistor of the sense amplifier.

The gate portion 810-a may include an edge 810-a-1, an edge 810-a-2, an edge 810-a-3, and an edge 810-a-4. The gate portion 810-b may include an edge 810-b-1, an edge 810-b-2, an edge 810-b-3, and an edge 810-b-4. The gate portion 810-c may include an edge 810-c-1, an edge 810-c-2, an edge 810-c-3, and an edge 810-c-4. The edge 810-b-3 may extend from the edge 810-a-3 in a first direction and the edge 810-c-4 may extend from the edge 810-a-4 in the first direction. The edge 810-b-2 may contact a first portion (e.g., segment) of the edge 810-a-1 and the edge 810-c-2 may contact a second portion of the edge 810-a-1, larger than the first portion of the edge 810-a-1.

The edge 810-b-3 may be offset from the edge 810-b-4 by a first distance 845-a and the edge 810-c-3 may be offset from the edge 810-c-4 by a second distance 845-b greater than the first distance 845-a. That is, the gate portion 810-b may be associated with a shorter height relative to the gate portion 810-c. The edge 805-a-1 may be aligned (e.g., on a vertical plane) with the edge 810-b-1 and the edge 810-c-1. The edge 810-a-3 may be offset from the edge 805-a-3 and the edge 810-a-4 may be offset from the edge 805-a-4.

Gate portions 810-d, 810-e, and 810-f, corresponding to another p-type transistor, may include an edge 810-d-1, an edge 810-d-2, an edge 810-d-3, an edge 810-d-4, an edge 810-e-1, an edge 810-e-2, an edge 810-e-3, an edge 810-e-4, an edge 810-f-1, an edge 810-f-2, an edge 810-f-3, and an edge 810-f-4, in like manner to the gate portions 810-a, 810-b, and 810-c, respectively, but with offsets (e.g., horizontal offsets) relative to the gate portions 810-a, 810-b, and 810-c. For example, the edge 810-a-1 may be offset from the edge 810-d-1 by a third distance 845-c and the edge 810-a-2 may be offset from the edge 810-d-2 by the third distance 845-c, offsetting the gate portion 810-a from the gate portion 810-d. Similarly, the 810-b may be offset from the gate portion 810-e, and the gate portion 810-c may be offset from the gate portion 810-f.

The shape of the gate portion 810, or the positioning of the source 830 and the drain 835, or both, illustrated in FIG. 8 is designed to increase a distance that carriers travel in the channel portion 805. For example, due to there being extra space in the channel portion 805 that overlaps the gate portion 810-c, and the source 830 being positioned relatively lower than the drain 835, carriers (e.g., a subset of carriers of a set of carriers passing through the channel portion 805) may travel according to a non-direct path (e.g., a U-shaped path), illustrated by the channel path 880. Because some carriers travel in a non-direct path between source and drain, due to a larger area of conductivity in the channel portion and the relative positions of the source 830 and the drain 835, a distance that carriers travel may increase relative to the gate portion 810 being a solid rectangle (e.g., a single rectangle without portions or offsets, for example, without the overhanging portions 810-c and/or 810-b). This increased distance reduces the variability of the threshold voltage in the p-type transistor, which decreases the variations in performance of a sense amplifier that includes such p-type transistors.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 1: A memory system, including: a memory cell; a digit line coupled with the memory cell; and a sense amplifier coupled with the digit line, the sense amplifier including: a n-type transistor; and a p-type transistor including: a source; a drain; a channel positioned between the source and the drain, the channel including a doped material configured to facilitate carriers flowing between the source and the drain, the channel including: a first portion coupled with the source, the first portion including a first edge, a second edge opposite the first edge, a third edge extending between the first edge and the second edge, and a fourth edge opposite the third edge; and a second portion coupled with the drain, the second portion including a fifth edge, a sixth edge opposite the fifth edge, a seventh edge extending between the fifth edge and the sixth edge, and an eighth edge opposite the seventh edge, where the fifth edge of the second portion is offset from the first edge of the first portion by a first distance, where the sixth edge of the second portion is offset from the second edge of the first portion by a second distance, where the seventh edge of the second portion is offset from the third edge of the first portion by a third distance, and where a portion of the fourth edge of the first portion contacts a portion of the seventh edge of the second portion; and a gate positioned above the channel and configured to control a quantity of the carriers flowing through the channel.

Aspect 2: The memory system of aspect 1, where the gate includes a ninth edge, a tenth edge opposite the ninth edge, a eleventh edge extending between the ninth edge and the tenth edge, and a twelfth edge opposite the eleventh edge, the ninth edge is offset from the fifth edge of the second portion by a fourth distance different from the first distance, the tenth edge is offset from the second edge of the first portion by a fifth distance that is different from the second distance.

Aspect 3: The memory system of any of aspects 1 through 2, where the sense amplifier further includes: a second p-type transistor including: a second source; a second drain; a second channel positioned between the second source and the second drain, the second channel including the doped material configured to facilitate the carriers flowing between the second source and the second drain, the second channel including: the second portion coupled with the second drain; and a third portion coupled with the second source, the third portion including a ninth edge, a tenth edge opposite the ninth edge, an eleventh edge extending between the ninth edge and the tenth edge, and a twelfth edge opposite the eleventh edge; and a second gate positioned above the second channel and configured to control a second quantity of the carriers flowing through the second channel.

Aspect 4: The memory system of aspect 3, where the ninth edge of the third portion is offset from the first edge of the first portion by a fourth distance different from the first distance, the tenth edge of the third portion is offset from the second edge of the first portion by a fifth distance different from the second distance.

Aspect 5: The memory system of any of aspects 3 through 4, where the gate includes a thirteenth edge, a fourteenth edge opposite the thirteenth edge, a fifteenth edge extending between the thirteenth edge and the fourteenth edge, and a sixteenth edge opposite the fifteenth edge, where the second gate includes a seventeenth edge, an eighteenth edge opposite the seventeenth edge, a nineteenth edge extending between the seventeenth edge and the eighteenth edge, and a twentieth edge opposite the nineteenth edge, where the thirteenth edge is offset from the seventeenth edge by a fourth distance different from the first distance and the second distance, where the fourteenth edge is offset from the eighteenth edge by the fourth distance

Aspect 6: The memory system of any of aspects 1 through 5, where the second edge of the first portion is set at an angle relative to the first edge of the first portion.

Aspect 7: The memory system of aspect 6, where the fifth edge of the second portion is set at the angle relative to the first edge of the first portion, the fifth edge of the second portion is parallel to the second edge of the first portion.

An apparatus is described. The following provides an overview of aspects of the apparatus as described herein:

Aspect 8: A memory system, including: a memory cell; a digit line coupled with the memory cell; and a sense amplifier coupled with the digit line, the sense amplifier including: a n-type transistor; and a p-type transistor including: a source; a drain; a channel positioned between the source and the drain, the channel including a doped material configured to facilitate carriers flowing between the source and the drain, the channel including a first edge, a second edge opposite the first edge, a third edge extending between the first edge and the second edge, and a fourth edge opposite the third edge; and a gate positioned above the channel and configured to control a quantity of the carriers flowing through the channel, the gate including: a first portion including a fifth edge, a sixth edge opposite the fifth edge, a seventh edge extending between the fifth edge and the sixth edge, and an eighth edge opposite the seventh edge, where the sixth edge of the first portion aligns with a portion of the second edge, where the seventh edge of the first portion is offset from the third edge by a first distance, and where the eighth edge of the first portion is offset from the fourth edge by a second distance; and a second portion including a ninth edge, a tenth edge opposite the ninth edge, an eleventh edge extending between the ninth edge and the tenth edge, and a twelfth edge opposite the eleventh edge, where the tenth edge of the second portion contacts a portion of the fifth edge of the first portion, and where the ninth edge of the second portion is offset from the first edge.

Aspect 9: The memory system of aspect 8, where the eleventh edge of the second portion is offset from the third edge by a third distance, the twelfth edge of the second portion is offset from the fourth edge by a fourth distance.

Aspect 10: The memory system of any of aspects 8 through 9, where the fifth edge of the first portion is offset from the first edge by a third distance.

Aspect 11: The memory system of any of aspects 8 through 10, where the sense amplifier further includes: a second p-type transistor including: a second source; a second drain; a second channel positioned between the second source and the second drain, the second channel including the doped material configured to facilitate the carriers flowing between the second source and the second drain, the second channel including a thirteenth edge, a fourteenth edge opposite the thirteenth edge, a fifteenth edge extending between the thirteenth edge and the fourteenth edge, and a sixteenth edge opposite the fifteenth edge; and a second gate positioned above the channel and configured to control a second quantity of the carriers flowing through the second channel, the second gate including: a third portion including a seventeenth edge, an eighteenth edge opposite the seventeenth edge, a nineteenth edge extending between the seventeenth edge and the eighteenth edge, and a twentieth edge opposite the nineteenth edge, where the seventeenth edge of the third portion aligns with a portion of the thirteenth edge, where the nineteenth edge of the third portion is offset from the fifteenth edge by the first distance, and where the twentieth edge of the third portion is offset from the sixteenth edge by the second distance; and a fourth portion including a twenty-first edge, a twenty-second edge opposite the twenty-first edge, a twenty-third edge extending between the twenty-first edge and the twenty-second edge, and a twenty-fourth edge opposite the twenty-third edge, where the twenty-first edge of the fourth portion contacts a portion of the eighteenth edge of the third portion, and where the twenty-second edge of the fourth portion is offset from the fourteenth edge.

Aspect 12: The memory system of aspect 11, where the thirteenth edge is offset from the second edge by a third distance, the seventeenth edge of the third portion is offset from the sixth edge of the first portion by the third distance.

An apparatus is described. The following provides an overview of aspects of the apparatus as described herein:

Aspect 13: A memory system, including: a memory cell; a digit line coupled with the memory cell; and a sense amplifier coupled with the digit line, the sense amplifier including: a n-type transistor; and a p-type transistor including: a source; a drain; a channel positioned between the source and the drain, the channel including a doped material configured to facilitate carriers flowing between the source and the drain, the channel including: a first portion coupled with the source, the first portion including a first edge, a second edge opposite the first edge, a third edge extending between the first edge and the second edge, and a fourth edge opposite the third edge; a second portion coupled with the drain, the second portion including a fifth edge, a sixth edge opposite the fifth edge, a seventh edge extending between the fifth edge and the sixth edge, and an eighth edge opposite the seventh edge; and a third portion including a ninth edge, a tenth edge opposite the ninth edge, an eleventh edge extending between the ninth edge and the tenth edge, and a twelfth edge opposite the eleventh edge, where the eleventh edge of the third portion extends from the third edge of the first portion in a first direction and the twelfth edge of the third portion extends from the eighth edge of the second portion in the first direction; and a gate positioned above the channel and configured to control a quantity of the carriers flowing through the channel, the gate including: a fourth portion including a thirteenth edge, a fourteenth edge opposite the thirteenth edge, a fifteenth edge extending between the thirteenth edge and the fourteenth edge, and a sixteenth edge opposite the fifteenth edge, where the thirteenth edge of the fourth portion is offset from the first edge of the first portion by a first distance, where the fifteenth edge of the fourth portion is offset from the third edge of the first portion by a second distance and the sixteenth edge of the fourth portion is offset from the third edge of the first portion by a third distance; a fifth portion including a seventeenth edge, an eighteenth edge opposite the seventeenth edge, a nineteenth edge extending between the seventeenth edge and the eighteenth edge, and a twentieth edge opposite the nineteenth edge; and a sixth portion including a twenty-first edge, twenty-second edge opposite the twenty-first edge, a twenty-third edge extending between the twenty-first edge and the twenty-second edge, and a twenty-fourth edge opposite the twenty-third edge, where a portion of the twenty-second edge of the sixth portion is aligned with the twelfth edge of the third portion.

Aspect 14: The memory system of aspect 13, where the seventeenth edge of the fifth portion is offset from the fifth edge of the second portion by the first distance.

Aspect 15: The memory system of any of aspects 13 through 14, where the twentieth edge of the fifth portion is offset from the eighth edge of the second portion by the second distance and the nineteenth edge of the fifth portion is offset from the eighth edge of the second portion by the third distance.

Aspect 16: The memory system of any of aspects 13 through 15, where the fourteenth edge of the fourth portion contacts a first portion of the twenty-first edge of the sixth portion and the eighteenth edge of the fifth portion contacts a second portion of the twenty-first edge of the sixth portion.

Aspect 17: The memory system of any of aspects 13 through 16, where the sense amplifier further includes: a second p-type transistor including: a second source; a second drain; a second channel positioned between the second source and the second drain, the second channel including the doped material configured to facilitate the carriers flowing between the second source and the second drain, the second channel including: a seventh portion coupled with the second source, the sixth portion including a twenty-fifth edge, a twenty-sixth edge opposite the twenty-fifth edge, a twenty-seventh edge extending between the twenty-fifth edge and the twenty-sixth edge, and a twenty-eighth edge opposite the twenty-seventh edge; an eighth portion coupled with the second drain, the second portion including a twenty-ninth edge, a thirtieth edge opposite the twenty-ninth edge, a thirty-first edge extending between the twenty-ninth edge and the thirtieth edge, and a thirty-second edge opposite the thirty-first edge; and a ninth portion including a thirty-third edge, a thirty-fourth edge opposite the thirty-third edge, a thirty-fifth edge extending between the thirty-third edge and the thirty-fourth edge, and a thirty-sixth edge opposite the thirty-fifth edge, where the thirty-fifth edge of the ninth portion extends from the twenty-seventh edge of the seventh portion in a second direction opposite the first direction and the thirty-sixth edge of the ninth portion extends from the thirty-second edge of the eighth portion in the second direction; and a second gate positioned above the channel and configured to control a second quantity of the carriers flowing through the channel, the gate including: a tenth portion including a thirty-seventh edge, a thirty-eighth edge opposite the thirty-seventh edge, a thirty-ninth edge extending between the thirty-seventh edge and the thirty-eighth edge, and a fortieth edge opposite the thirty-ninth edge, where the thirty-ninth edge of the tenth portion is offset from the twenty-seventh edge of the seventh portion by the second distance and the fortieth edge of the tenth portion is offset from the twenty-seventh edge of the seventh portion by the third distance; an eleventh portion including a forty-first edge, a forty-second edge opposite the forty-first edge, a forty-third edge extending between the forty-first edge and the forty-second edge, and a forty-fourth edge opposite the forty-third edge; and a twelfth portion including a forty-fifth edge, a forty-sixth edge opposite the forty-fifth edge, a forty-seventh edge extending between the forty-fifth edge and the forty-sixth edge, and a forty-eighth edge opposite the forty-seventh edge, where a portion of the forty-fifth edge of the twelfth portion is aligned with the thirty-third edge of the ninth portion.

Aspect 18: The memory system of aspect 17, where the tenth edge of the third portion is offset from the thirty-third edge of the ninth portion by a fourth distance.

Aspect 19: The memory system of any of aspects 13 through 18, where the fourth edge of the first portion is offset from the seventh edge of the second portion by a fourth distance.

Aspect 20: The memory system of any of aspects 13 through 19, where the thirteenth edge of the fourth portion is offset from the twenty-first edge of the sixth portion by a fourth distance and the seventeenth edge of the fifth portion is offset from the twenty-first edge of the sixth portion by the fourth distance.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
a memory cell;
a digit line coupled with the memory cell; and
a sense amplifier coupled with the digit line, the sense amplifier comprising:
a n-type transistor; and
a p-type transistor comprising:
a source;
a drain;
a channel positioned between the source and the drain, the channel comprising a doped material configured to facilitate carriers flowing between the source and the drain, the channel comprising:
a first portion coupled with the source, the first portion comprising a first edge, a second edge opposite the first edge, a third edge extending between the first edge and the second edge, and a fourth edge opposite the third edge; and
a second portion coupled with the drain, the second portion comprising a fifth edge, a sixth edge opposite the fifth edge, a seventh edge extending between the fifth edge and the sixth edge, and an eighth edge opposite the seventh edge,
wherein the fifth edge of the second portion is offset from the first edge of the first portion by a first distance,
wherein the sixth edge of the second portion is offset from the second edge of the first portion by a second distance,
wherein the seventh edge of the second portion is offset from the third edge of the first portion by a third distance, and
wherein a portion of the fourth edge of the first portion contacts a portion of the seventh edge of the second portion; and
a gate positioned above the channel and configured to control a quantity of the carriers flowing through the channel.

2. The memory system of claim 1, wherein the gate comprises a ninth edge, a tenth edge opposite the ninth edge, an eleventh edge extending between the ninth edge and the tenth edge, and a twelfth edge opposite the eleventh edge, and
wherein the ninth edge is offset from the fifth edge of the second portion by a fourth distance different from the first distance and the tenth edge is offset from the second edge of the first portion by a fifth distance that is different from the second distance.

3. The memory system of claim 1, wherein the sense amplifier further comprises:
a second p-type transistor comprising:
a second source;
a second drain;
a second channel positioned between the second source and the second drain, the second channel comprising the doped material configured to facilitate the carriers flowing between the second source and the second drain, the second channel comprising:
the second portion coupled with the second drain; and
a third portion coupled with the second source, the third portion comprising a ninth edge, a tenth edge opposite the ninth edge, an eleventh edge extending between the ninth edge and the tenth edge, and a twelfth edge opposite the eleventh edge; and
a second gate positioned above the second channel and configured to control a second quantity of the carriers flowing through the second channel.

4. The memory system of claim 3, wherein the ninth edge of the third portion is offset from the first edge of the first portion by a fourth distance different from the first distance and the tenth edge of the third portion is offset from the second edge of the first portion by a fifth distance different from the second distance.

5. The memory system of claim 3, wherein the gate comprises a thirteenth edge, a fourteenth edge opposite the thirteenth edge, a fifteenth edge extending between the thirteenth edge and the fourteenth edge, and a sixteenth edge opposite the fifteenth edge,
wherein the second gate comprises a seventeenth edge, an eighteenth edge opposite the seventeenth edge, a nineteenth edge extending between the seventeenth edge and the eighteenth edge, and a twentieth edge opposite the nineteenth edge, and
wherein the thirteenth edge is offset from the seventeenth edge by a fourth distance different from the first distance and the second distance and the fourteenth edge is offset from the eighteenth edge by the fourth distance.

6. The memory system of claim 1, wherein the second edge of the first portion is set at an angle relative to the first edge of the first portion.

7. The memory system of claim 6, wherein the fifth edge of the second portion is set at the angle relative to the first edge of the first portion and the fifth edge of the second portion is parallel to the second edge of the first portion.

8. A memory system, comprising:
a memory cell;
a digit line coupled with the memory cell; and
a sense amplifier coupled with the digit line, the sense amplifier comprising:
a n-type transistor; and
a p-type transistor comprising:
a source;
a drain;
a channel positioned between the source and the drain, the channel comprising a doped material configured to facilitate carriers flowing between the source and the drain, the channel comprising a first edge, a second edge opposite the first edge, a third edge extending between the first edge and the second edge, and a fourth edge opposite the third edge; and
a gate positioned above the channel and configured to control a quantity of the carriers flowing through the channel, the gate comprising:
a first portion comprising a fifth edge, a sixth edge opposite the fifth edge, a seventh edge extending between the fifth edge and the sixth edge, and an eighth edge opposite the seventh edge,
wherein the sixth edge of the first portion aligns with a portion of the second edge,
wherein the seventh edge of the first portion is offset from the third edge by a first distance, and
wherein the eighth edge of the first portion is offset from the fourth edge by a second distance; and
a second portion comprising a ninth edge, a tenth edge opposite the ninth edge, an eleventh edge extending between the ninth edge and the tenth edge, and a twelfth edge opposite the eleventh edge,
wherein the tenth edge of the second portion contacts a portion of the fifth edge of the first portion, and
wherein the ninth edge of the second portion is offset from the first edge.

9. The memory system of claim 8, wherein the eleventh edge of the second portion is offset from the third edge by a third distance and the twelfth edge of the second portion is offset from the fourth edge by a fourth distance.

10. The memory system of claim 8, wherein the fifth edge of the first portion is offset from the first edge by a third distance.

11. The memory system of claim 8, wherein the sense amplifier further comprises:
a second p-type transistor comprising:
a second source;
a second drain;
a second channel positioned between the second source and the second drain, the second channel comprising the doped material configured to facilitate the carriers flowing between the second source and the second drain, the second channel comprising a thirteenth edge, a fourteenth edge opposite the thirteenth edge, a fifteenth edge extending between the thirteenth edge and the fourteenth edge, and a sixteenth edge opposite the fifteenth edge; and
a second gate positioned above the channel and configured to control a second quantity of the carriers flowing through the second channel, the second gate comprising:
a third portion comprising a seventeenth edge, an eighteenth edge opposite the seventeenth edge, a nineteenth edge extending between the seventeenth edge and the eighteenth edge, and a twentieth edge opposite the nineteenth edge,
wherein the seventeenth edge of the third portion aligns with a portion of the thirteenth edge,
wherein the nineteenth edge of the third portion is offset from the fifteenth edge by the first distance, and
wherein the twentieth edge of the third portion is offset from the sixteenth edge by the second distance; and
a fourth portion comprising a twenty-first edge, a twenty-second edge opposite the twenty-first edge, a twenty-third edge extending between the twenty-first edge and the twenty-second edge, and a twenty-fourth edge opposite the twenty-third edge,
wherein the twenty-first edge of the fourth portion contacts a portion of the eighteenth edge of the third portion, and
wherein the twenty-second edge of the fourth portion is offset from the fourteenth edge.

12. The memory system of claim 11, wherein the thirteenth edge is offset from the second edge by a third distance and the seventeenth edge of the third portion is offset from the sixth edge of the first portion by the third distance.

13. A memory system, comprising:
a memory cell;
a digit line coupled with the memory cell; and
a sense amplifier coupled with the digit line, the sense amplifier comprising:
a n-type transistor; and
a p-type transistor comprising:
a source;
a drain;
a channel positioned between the source and the drain, the channel comprising a doped material configured to facilitate carriers flowing between the source and the drain, the channel comprising:
a first portion coupled with the source, the first portion comprising a first edge, a second edge opposite the first edge, a third edge extending between the first edge and the second edge, and a fourth edge opposite the third edge;
a second portion coupled with the drain, the second portion comprising a fifth edge, a sixth edge opposite the fifth edge, a seventh edge extending between the fifth edge and the sixth edge, and an eighth edge opposite the seventh edge; and
a third portion comprising a ninth edge, a tenth edge opposite the ninth edge, an eleventh edge extending between the ninth edge and the tenth edge, and a twelfth edge opposite the eleventh edge,
wherein the eleventh edge of the third portion extends from the third edge of the first portion in a first direction and the twelfth edge of the third portion extends from the eighth edge of the second portion in the first direction; and
a gate positioned above the channel and configured to control a quantity of the carriers flowing through the channel, the gate comprising:
a fourth portion comprising a thirteenth edge, a fourteenth edge opposite the thirteenth edge, a fifteenth edge extending between the thirteenth edge and the fourteenth edge, and a sixteenth edge opposite the fifteenth edge,
wherein the thirteenth edge of the fourth portion is offset from the first edge of the first portion by a first distance, and
wherein the fifteenth edge of the fourth portion is offset from the third edge of the first portion by a second distance and the sixteenth edge of the fourth portion is offset from the third edge of the first portion by a third distance;
a fifth portion comprising a seventeenth edge, an eighteenth edge opposite the seventeenth edge, a nineteenth edge extending between the seventeenth edge and the eighteenth edge, and a twentieth edge opposite the nineteenth edge; and
a sixth portion comprising a twenty-first edge, twenty-second edge opposite the twenty-first edge, a twenty-third edge extending between the twenty-first edge and the twenty-second edge, and a twenty-fourth edge opposite the twenty-third edge,
wherein a portion of the twenty-second edge of the sixth portion is aligned with the twelfth edge of the third portion.

14. The memory system of claim 13, wherein the seventeenth edge of the fifth portion is offset from the fifth edge of the second portion by the first distance.

15. The memory system of claim 13, wherein the twentieth edge of the fifth portion is offset from the eighth edge of the second portion by the second distance and the nineteenth edge of the fifth portion is offset from the eighth edge of the second portion by the third distance.

16. The memory system of claim 13, wherein the fourteenth edge of the fourth portion contacts a first portion of the twenty-first edge of the sixth portion and the eighteenth edge of the fifth portion contacts a second portion of the twenty-first edge of the sixth portion.

17. The memory system of claim 13, wherein the sense amplifier further comprises:
a second p-type transistor comprising:
a second source;
a second drain;
a second channel positioned between the second source and the second drain, the second channel comprising the doped material configured to facilitate the carriers flowing between the second source and the second drain, the second channel comprising:
a seventh portion coupled with the second source, the sixth portion comprising a twenty-fifth edge, a twenty-sixth edge opposite the twenty-fifth edge, a twenty-seventh edge extending between the twenty-fifth edge and the twenty-sixth edge, and a twenty-eighth edge opposite the twenty-seventh edge;
an eighth portion coupled with the second drain, the second portion comprising a twenty-ninth edge, a thirtieth edge opposite the twenty-ninth edge, a thirty-first edge extending between the twenty-ninth edge and the thirtieth edge, and a thirty-second edge opposite the thirty-first edge; and
a ninth portion comprising a thirty-third edge, a thirty-fourth edge opposite the thirty-third edge, a thirty-fifth edge extending between the thirty-third edge and the thirty-fourth edge, and a thirty-sixth edge opposite the thirty-fifth edge,
wherein the thirty-fifth edge of the ninth portion extends from the twenty-seventh edge of the seventh portion in a second direction opposite the first direction and the thirty-sixth edge of the ninth portion extends from the thirty-second edge of the eighth portion in the second direction; and
a second gate positioned above the channel and configured to control a second quantity of the carriers flowing through the channel, the gate comprising:
a tenth portion comprising a thirty-seventh edge, a thirty-eighth edge opposite the thirty-seventh edge, a thirty-ninth edge extending between the thirty-seventh edge and the thirty-eighth edge, and a fortieth edge opposite the thirty-ninth edge,
wherein the thirty-ninth edge of the tenth portion is offset from the twenty-seventh edge of the seventh portion by the second distance and the fortieth edge of the tenth portion is offset from the twenty-seventh edge of the seventh portion by the third distance;
an eleventh portion comprising a forty-first edge, a forty-second edge opposite the forty-first edge, a forty-third edge extending between the forty-first edge and the forty-second edge, and a forty-fourth edge opposite the forty-third edge; and
a twelfth portion comprising a forty-fifth edge, a forty-sixth edge opposite the forty-fifth edge, a forty-seventh edge extending between the forty-fifth edge and the forty-sixth edge, and a forty-eighth edge opposite the forty-seventh edge,
wherein a portion of the forty-fifth edge of the twelfth portion is aligned with the thirty-third edge of the ninth portion.

18. The memory system of claim 17, wherein the tenth edge of the third portion is offset from the thirty-third edge of the ninth portion by a fourth distance.

19. The memory system of claim 13, wherein the fourth edge of the first portion is offset from the seventh edge of the second portion by a fourth distance.

20. The memory system of claim 13, wherein the thirteenth edge of the fourth portion is offset from the twenty-first edge of the sixth portion by a fourth distance and the seventeenth edge of the fifth portion is offset from the twenty-first edge of the sixth portion by the fourth distance.
